(19) United States
(12) Patent Application Publication
(10) Pub. No.: US 2007/0253260 A1
(43) Pub. Date: Nov. 1, 2007

(54) Integrating the Internet system of mediation of financial loans, purchase of goods and providing services

(76) Inventors: Jan Pavlis, Kosice (SK); Alena Pavlisova, Kosice (SK)

Correspondence Address: DONN K. HARMS;PATENT & TRADEMARK LAW CENTER, SUITE 100, 12702 VIA CORTINA, DEL MAR, CA, 92014, US

(21) Appl. No.: 11/789,487

(22) Filed: Apr. 24, 2007

(30) Foreign Application Priority Data
Apr. 26, 2006 (SK) PUV 98-2006
Jul. 24, 2006 (SK) PUV 148-2006
Aug. 10, 2006 (SK) PUV176-2006

(51) Int. Cl. G11C 7/10

(52) U.S. Cl. 365/189.02

(57) ABSTRACT

An Internet based system and method for mediation of financial loans, purchasing goods and providing services between consumers and providers which employs a mediator therebetween. The system employs a public communication network such as the Internet, to interconnect at least one mediator between at least one creditor, and a client. Over a public networking system, the system provides verification of client identity through the mediator, communication of loan terms from the creditor through the mediator to a client, and accounting of each party's ongoing financial interests via software resident on a bank or other financial institution's computer. The system thereby provides clients seeking financial surfaces or goods access to providers thereof over a public network through a mediator and a subsequent accounting for all three parties' mutual interests employing software adapted to the task running on a mutually accessible computer or server.

### TECHNICAL FIELD

The technical solution concerns the integration of the Internet system of mediating financial loans, purchase of goods and providing services designed for the market subjects.

### PRIOR STATE OF THE ART

At the present time the delivery of financial loans is carried out by the way of personal contact of the creditor and debtor who have been connected by a mediator in some cases. The disadvantage of this settlement is that there has not been any space for the mass character and availability of the loans while the interest rate achieved a very high level in most of the cases not acceptable for the debtors. This prevented the more efficient development of the market and the movement of goods and services.

Further well-known solution has been described in the Slovak patent document P No. 284 504 with priority from the Czech application of utility model PÚV No. 8 804-98 entitled “System on electronic cashless purchase of goods and services through cards”, which contains a block of bank operations that is connected by means of credit card with the block of the holder of the credit card for sending data on goods or services accessible via block of the operator of the seller with identification of this block of the seller's operator, while the block of the holder of the credit card is additionally connected with the block of the seller's operator who is interconnected on one side with the block of bank operations with credit card and on the other side it is connected at least with one block of supplier of goods or services. The disadvantage of this settlement rests in the fact that it is not applicable in the field of mediation of monetary loans.

Another noted settlement has been given in the published Slovak patent application PP No. 1 441-2003 entitled “Equipment for safe system of payments applicable for micro-payments” which consists of three or more sub-devices while these subordinated devices are implemented by the help of specialized hardware equipment or by way of computer and a respective program from which one of the above sub-devices serves to the provider for providing information for some consideration, the next enables the customer to buy and mediate information, and the third one ensures the administrator to keep the customers' account. All of the shown participants can connect with the others through communication network, and the values of the cryptographic heavy one-way hash function are used up for ensuring the money transfer and authorization of the agents participating at the transactions while the initialization of the system of payments does not require any preparation through a secured channel. Moreover, only one operation is needed by the help of cryptography “method of public key” for the distribution of the published secret information among the agents, and any of the subsequent transactions requires only the calculation of some values of the hash function which creates an equipment for efficient, cheap and fast micro-payment contacts. The disadvantage of this solution is its limited application only in the field of purchase and mediation of information for payment.

The next technical solution has been given in the published Slovak patent application PP No. 746-2003 with priority from two Czech patent applications PP No. 2002-3 265 and PP No. 2002-13 521 entitled “Communication infrastructure of a cooperating corporation” which has been established from the system of virtual private networks of transmission infrastructure of providers. They are connected in individual locations on the interface of a universal feeder with the local computer networks. These elements create internal communication networks of the cooperating corporation aimed, especially, at mutual sharing of services of the communication infrastructure of the corporation. The disadvantage of this solution lies in the fact that it is inapplicable in the field of mediation of monetary loans and in the field of mediation of purchase of goods and provision of services.

Another settlement has been described in the published Slovak patent application PP No. 1 165-2000 with priority of Spanish patent application PP No. 2000 00724, PP No. 2000 01573 and PP No. 2000 01574 entitled “System for processing payments and transactions among the payers and beneficiaries and the method of processing these payments”. The payers and beneficiaries are connected to the system using the first server interconnected through telecommunication media with the first devices serving for memorizing data, containing information on each connected payer. This information comprises at least the permitted telephone number, the authorizing criterion permitting transactions and the security criterion assigned to the permitted telephone number as well as the permitted identification code of every beneficiary; the second devices for memorizing data, containing information regarding the type of digital mobile phone, pertaining to every telephone number; the selective facilities for choosing one of the telecommunication device which communicate with the digital mobile phone identified by the permitted phone number by the help of telecommunication services that is compatible with the given type of digital mobile phone as it has been identified. The disadvantage of this solution lies in the fact that it is inapplicable in the field of mediation of monetary loans and in the filed of mediation of purchase of goods and providing services.

Further solution is characterized in the published Slovak patent application PP No. 596-2000 with priority from the American patent application PP No. 60/099 152 entitled “Electronic commerce with anonymous shopping and with anonymous vendor shipping”, wherein the delivery of the goods purchased from the vendor's/retailer's server is carried out via computers without disclosing the customer's identity or his/her physical address with allocation of every customer's identity and physical address onto the computer through some connecting information saved in a secured computer. These computers might be the ones of the reliable supplier or the computer of the bank where the customer's computer is being anonymously connected onto the server of the vendor's computer where the buyer may order any goods without disclosure of his/her real identity or physical address, and the retailer hands on the goods to a common carrier. The goods are given in packages provided with the transaction-identifier and the customer's address. This way the common carrier is informed about the customer's identity and address from the computer of the reliable supplier using the transaction identifier or the customer's address and he/she will be able to deliver the package onto the customer's physical address. The disadvantage of this solution lies in the fact that it is applicable only in the field of purchase upon reimbursement.

The next solution was characterized in the published Slovak patent application PP No. 1 426-1997 with priority from the American patent application PP No. 08/427 287 entitled “Electronic monetary system”. In this system the banks or financial institutions are coupled to a money generator device for generating and issuing to subscribing customers electronic money including electronic currency backed by demand deposits and electronic credit authorizations; the correspondent banks that accept and distribute the electronic money; a plurality of transaction devices used by subscribers for storing electronic money, for carrying out money transactions with the on-line systems of the participating banks or for exchanging electronic money with other transaction devices in off-line transactions without connection with the central computer; automatic teller machines associated with the issuing and correspondent banks, for process handling and interfacing the mentioned transaction devices to the issuing and correspondent banks, and for interfacing between the issuing and correspondent banks themselves; a clearing bank for balancing the provisional money accounts of different issuing banks; a data communications network for providing communication services to all components of the system; and security measures for maintaining the integrity of the system, and for detecting counterfeiting and tampering within the system. An embodiment of the invention includes a customer service module which handles lost money claims and links accounts to money modules for providing bank access. The disadvantage of this technical settlement is that it is inapplicable in mediation of monetary loans, in the field of mediation of purchase of goods or providing services.

The next well-known solution has been described in published Czech patent application PP c. 2002-744 with priority from American patent applications PP No. 1999 151880, PP No. 1999 164668, PP No. 1999 165577 and PP No. 2000 201635 entitled “Methods and devices for making electronic transactions” where the electronic transaction is a purchase transaction while the user is provided by an intelligent character, for example a chip card containing a digital certificate where the intelligent character is authorized at the server in the network in a way that it keeps all the transaction on behalf of the user, the wallet server cooperates with the safety server in order to provide enhanced reliability and credibility during transactions. It involves a toolbar and the digital wallet fills out forms that might be completed already in advance by use of the item of the automatic memory. The disadvantage of this solution lies in the fact that it is applicable only in the field of purchase upon reimbursement.

The following solution is the one published in Czech patent application PP No. 2000-4 781 with priority from the American patent application PP No. 1998 089825 entitled “Verified payment system” where VPS provides mediation to all participants in safe electronic and digital transactions while this VPS involves a verified guarantor registration system enabling safe, private registration of identification, verifying and paying data both of the clients and sellers. This involves also payment systems, including banks and the generator of verifying records serving for creating the verifying record on the relevant electronic/digital transaction. Additionally the verifying record is accessible to all participants of electronic/digital transaction; the system embodies a large number of hubs/switches, connected with private network and also with the seller, client and payment system. These hubs/switches are equipped by means for the independent communication of seller and client with the system of VPS, they have also a registration authorization ensuring registration services that specify which hub/switch supports which client and the safe transactions shown above are mediated without direct communication between the participants. The disadvantage of this solution rests in the fact that it is inapplicable in the field of mediation of monetary loans and in the field of mediation of purchase of goods and providing services.

The next solution is the one described in the published Czech patent application PP No. 2000-4 103 entitled “Integrating the system for business mediation between participants currently interconnected with the public communication network”—which is made up of series of mutually interconnected user devices that are connected with the central system also and where the central device contains the central annotation database which is then connected at one input with the databases of annotations of the user's items of all really interconnected user devices which together with the database of the enhanced information create the database of the items of the user. At the second input there is a connection with the module of search that is connected with the display module of search at the next output. The central database of annotations is interconnected on its output with the module of display of the searched items, which on its second output is interconnected with the databases of enhanced information of further user equipments whose items are displayed in the module of display of the searched items. The latter is interconnected on its output with the work module with the searched items while the database of the user items is interconnected with the module of creation and administration of items that is connected on its output with the module of display of creation and administration of items. The disadvantage of this solution lies in the fact that it is applicable only in the field of purchase of information, products and services.

A new solution is described in the published Czech patent application PP No. 2000-3 501 entitled “System solution of the E-business and access to the information sources, products and services”. In this system there is a closed network comprising a group of servers set up into independent network with ensured communication with the environment, ensured mediated and guaranteed access of clients via interface under condition that the interface is a place from which all the internal client services are made, and where the closed network environment is made up of servers arranged into a structure where the central server is placed on the top of the closed network. Minimally one national server and the server operator make the lower level and the server operator is communicatively connected with the clients. The interface makes a user-environment established by special means i.e. software settlement, hardware settlement and organization means where the mediated access is an indirect link between the client and source and it is generated by the module of safeguarding the interface and by the module of client safety. The disadvantage of this solution rests in the fact that it is inapplicable in the field of mediation of monetary loans and in the field of mediation of purchase of goods or providing services.

Another known solution is the published Czech patent application PP No. 1998-598 with priority from American patent application PP No. 1995 002856 entitled “Anonymous business system with improved characteristics for entering price-offers” wherein the system shall define in all price offers entered into the anonymous computer business system whether it is expected that it will be a significant item in essential number of point of sale, and if this is the case it will inform the businessman who has made the price offer. A significant number of points of sale is expressed by the advantage bigger than the predefined percentage of the suitable business partners with whom the credit has been negotiated on the bilateral basis and it is more than 25% where in alternative version it provides for the market-maker, from whom the price offer came, a graphic display informing about the fact that how many points of sale are well balanced in order to accept the concerned price offer and/or the numeric display shows the price that might be a relevant item within a predetermined number or percentage of suitable business partners. The disadvantage of this resolution rests in the fact that it is applicable only in the field of purchase of products and services.

### Essence of the Technical Solution

The described shortages are significantly removed by integrating the internet system aimed at mediation of financial loans, purchasing goods and providing services designed for market subjects pursuant to this engineering solution. Its essence rests in the fact that it has been made up of minimally one mediator block that is interconnected via a transmission channel with at least one creditor block and/or one bank block and/or with at least one provider block and/or at least one security block and/or at least one external block and/or at least one client's block which is interconnected through a transmission channel with at least one verifying block which is connected by a transmission channel with at least one verifying block and/or at least one provider block and/or at least one mediator block.

It is an advantage that at least one client block is interconnected through a transmission channel with at least one creditor's block and/or at least one provider's block and/or at least one security block that is interconnected by means of transmission channel with at least one creditor's block and/or with at least provider's block.

The described shortages are also significantly removed by integrating the Internet system of mediation of financial loans designed for financial mediation for the market subjects pursuant to this engineering solution. Its essence rests in the fact that it is made up of at least one mediator block that is interconnected via transmission channel with at least one creditor block and/or at least one client's block and/or at least one bank block that is from one side connected by a transmission channel with at least one creditor's block and/or at least one client's block that is connected through a transmission channel with at least one creditor's block.

It is an advantage that at least one client's block interconnected by means of transmission channel with at least one verifying block that is connected through a transmission channel with at least one creditor's block and/or at least one bank block and/or at least one mediator block.

The system of verification of the client's identity designed for providing financial loans for the market subjects pursuant to this technical solution rests in the fact that it has been made up minimally of one client's block that is interconnected via a transmission channel with at least one provider's block and it is interconnected through a transmission channel with at least one verifying block which is connected by a transmission channel with at least one provider's block that is interconnected via transmission channel with at least bank block which is interconnected via transmission channel with at least client's block.

It is an advantage that at least one provider's block and/or at least one client's block is interconnected through a transmission channel with at least one creditor's block that is interconnected by means of transmission channel with at least one bank block which is interconnected via transmission channel with at least one client's block.

### DESCRIPTION OF THE DRAWINGS

The engineering solution is going to be explained in more details through the drawings No. 1,2,3 and 4 which describe a schematic presentation of the connection of Internet system of mediation of financial loans, purchasing goods and providing services.

### EXAMPLES OF IMPLEMENTATION

### Example No. 1

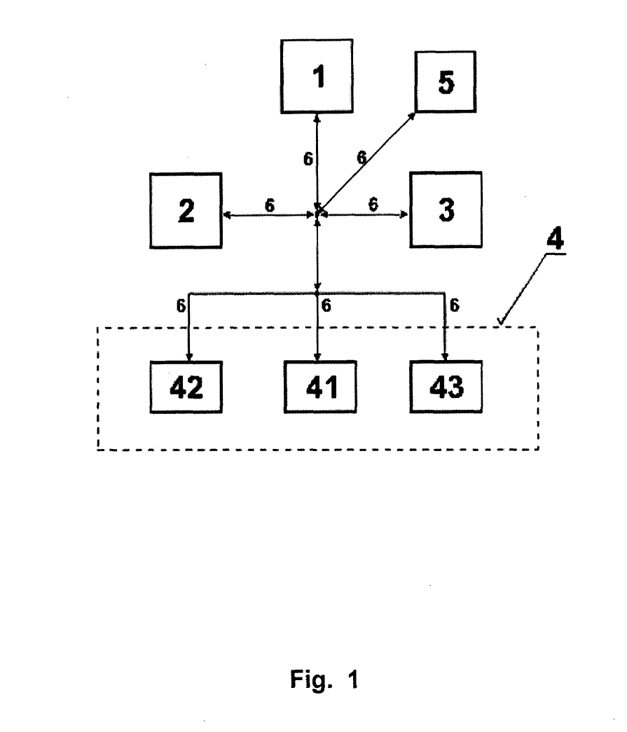

The connection of the Internet system for mediation of financial loans, designed for market subjects pursuant to FIG. 1 that is formed by the creditors block 2 i.e. the computer terminal of the provider of the financial loan. The creditor's block 2 is interconnected through the transmission channel 6 with the mediator block 1 that is the registration-controlling port of the mediator. From the other side the mediator block 1 is interconnected through the transmission channel 6 with the client block 3 which is the computer terminal of the client. The mediator block 1 is connected from the other side via the transmission channel 6 with the mediator accounting module 41 of the bank block 4 that is the mediator's account. The bank block 4 which is the computer terminal of the bank is made up of mutually interconnected mediator accounting module 41 and creditor accounting module 42 and client accounting module 43. The client accounting module 43 is interconnected through the transmission channel 6 with the client's block 3. The creditor's accounting module 42 is interconnected through the transmission channel 6 with the creditor's block 2. The mediator accounting block 41 is connected through the transmission channel 6 with the mediator block 1. The mediator accounting block 41 is connected through the transmission channel 6 with the creditor block 2. The mediator accounting block 41 is connected through the transmission channel 6 with client's block 3.

### Example No. 2

The connection of the Internet system for mediation of financial loans designed for market subjects pursuant to FIG. 1 is formed by the creditor's block 2 i.e. the computer terminal of the provider of the financial loan. The creditor's block 2 is interconnected through the transmission channel 6 with the verifying block 5 which identifies and verifies the client's credibility. The creditor's block 2 is then interconnected through the transmission channel 6 with the mediator block 1 that is the registration-controlling port of the mediator. The mediator block 1 is further connected through the transmission channel 6 with the verifying block 5. The mediator's block 1 is from the other side connected through the transmission channel 6 with the client's block 3 that is the computer terminal of the client. The client's block 3 is connected from the next side through the transmission channel 6 with the verifying block 5 that identifies and verifies the client's credibility. The mediator block 1 is connected from the other side through the transmission channel 6 with the mediator accounting module 41 of the bank block 4 which is the mediator's account. The bank block 4 that is the computer terminal of the bank is created from the mutually interconnected mediator accounting module 41, the creditor's accounting module 42 and client's accounting module 43. The client's accounting module 43 is connected through the transmission channel 6 with the client's block 3. The creditor's accounting module 42 is connected through the transmission channel 6 with the creditor's block 2. The mediator accounting block 41 is connected through the transmission channel 6 with the mediator block 1. The mediator accounting block 41 is connected through the transmission channel 6 with the creditor's block 2. The mediator accounting block 41 is connected through the transmission channel 6 with the client's block 3.

### Example No. 3

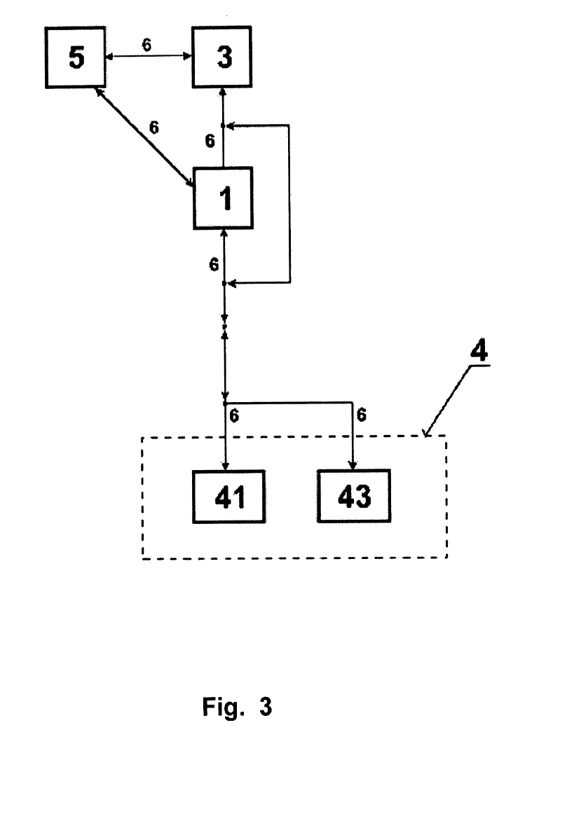

The connection of the internet system for mediation of financial loans, purchasing goods and providing services, designed for market subjects pursuant to FIG. 3 that is formed by the creditor's block 2 i.e. the computer terminal of the provider of the financial loan. The creditor's block 2 is interconnected through the transmission channel 6 with the mediator block 1 that is the registration-controlling port. The creditor's block 2 is interconnected through the mediator block 1 with the client block 3, which is the computer terminal of the person interested in financial loan for purchasing a package holiday. The mediator block 1 is connected from the other side by means of the transmission channel 6 with the verifying block 5 which is identical to the computer terminal for identification and verification of the solvency. From the additional side the mediator block 1 is interconnected through the transmission channel 6 with the provider block 8 that is the computer terminal of a travel agency. From additional side the mediator block 1 is interconnected through the transmission channel 6 with the security block 9, that is the computer terminal of the lawyer's office ensuring fulfillment of the contractual relations. From the further side the mediator block 1 is connected with external block 7 through the transmission channel 6. The external block 7 is the computer terminal of the provider of the external database with the providers of financial loans, with providers of services and goods. The mediator block 1 is connected via transmission channel 6 from the further side with the bank block 4 that is the computer terminal of the bank. The bank block 4 comprises the mutually interconnected mediator accounting module 41, the creditor's accounting module 42, external accounting module 47, the security accounting module 48 and client accounting module 43. The mediator accounting module 41 which equals to the account of the mediator is connected via the transmission channel 6 with the mediator block 1. The client's accounting module 43, which is the client's account, is interconnected with the client's block 3 through the transmission channel 6. The creditor's accounting module 42 that is the creditor's account is connected with the creditor's block 2 through transmission channel 6. The external accounting module 47 that is the account of the provider of the external database is by transmission channel 6 connected with the external block 7. The provider's accounting module 48, i.e. the account of the travel agency is through the transmission channel 6 connected with the provider's block 8. The provider's block 8 is through the transmission channel 6 connected with the security block 9. This security block 9 is through the transmission channel 6 connected with the creditor's block 2. The creditor's block 2 is interconnected by transmission channel 6 with the mediator accounting module 41. This mediator accounting module 41 is interconnected through the transmission channel 6 by the client block 3. The client block 3 is connected through the transmission channel 6 with the client accounting module 43. The mediator accounting module 41 is connected through the transmission channel 6 with the verifying block 5. This verifying block 5 is connected through the transmission channel 6 with the client's block 3. The verifying block 5 then from the other side is being connected through the transmission channel 6 with the creditor's block 2. The verifying block 5 is being connected from the other side through the transmission channel 6 with the provider's block 8. The mediator accounting module 41 is connected through the transmission channel 6 with the external block 7. The mediator accounting module 41 is connected through the transmission channel 6 with the provider's block 8. The provider's block 8 is interconnected via transmission channel 6 with the security 9. The security block 9 is interconnected from the other side with the creditor's block 2. The security block 9 is interconnected from next side with the client's block 3.

### Example No. 4

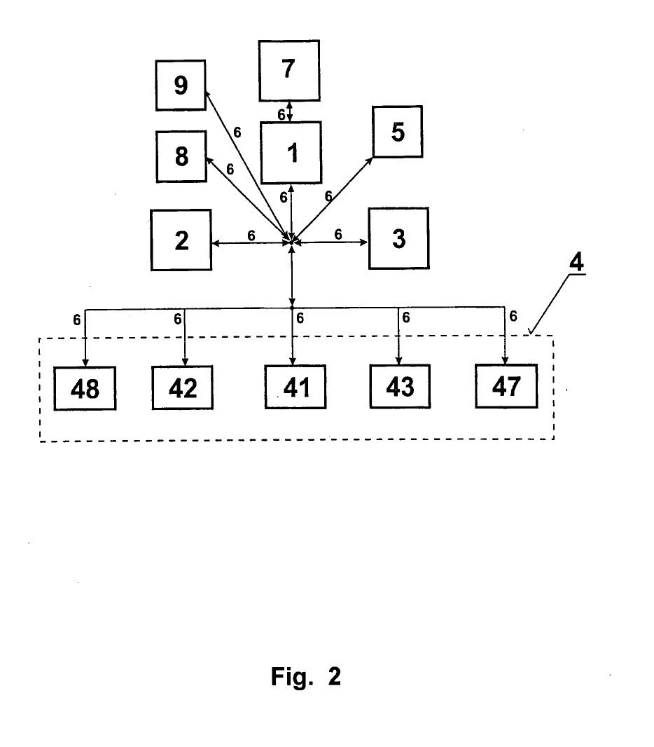

The integration of internet system for mediation of financial loans, purchasing goods and providing services designed for market subjects pursuant to FIG. 2 that is formed by the creditor's block 2 i.e. the computer terminal of the provider of the financial loan. The creditor's block 2 is interconnected through the transmission channel 6 with the mediator block 1 which is the registration-controlling port. The creditor's block 2 is interconnected via mediator's block 1 with the client's block 3 that is the customer's computer terminal who is interested in financial loan for the purpose of purchasing real assets. The mediator block 1 is from the other side connected through the transmission channel 6 with the verifying block 5 that is the computer terminal serving for identification and verification of credibility. The mediator's block 1 is from the next side connected through the transmission channel 6 with the provider's block 8 that is the computer terminal of the real estate agency. The mediator block 1 is connected from the next side through the transmission channel 6 with the security block 9 that is the computer terminal of the office of the distrainer ensuring debt recovery following from contractual relations. The mediator block 1 is connected from the next side through the transmission channel 6 with the external block 7 that is the computer terminal of the provider of the external database including providers of financial loans and providers of services and goods. The mediator block 1 is connected from the other side through the transmission channel 6 with the bank block 4 i.e. the computer terminal of the bank. The bank block 4 is created from mutually interconnected mediator accounting module 41, the creditor accounting module 42, the external accounting module 47, security accounting module 48 and client accounting module 43. The mediator accounting module 41 identical with the mediator's account is connected through the transmission channel 6 with the mediator block 1. The client's accounting module 43 that is the client's account is connected through the transmission channel 6 with the client block 3. The creditor's accounting module 42 that is the creditor's account is connected through the transmission channel 6 with the creditor's block 2. The external accounting module 47 that is the account of the external database provider is connected through the transmission channel 6 with the external block 7. The provider's accounting module 48 that is the account of the real estate agency is connected through the transmission channel 6 with the provider's block 8. The provider's block 8 is connected through the transmission channel 6 with the security block 9. The security block 9 is connected through the transmission channel 6 with the creditor's block 2. The creditor's block 2 is connected through the transmission channel 6 with the mediator accounting module 41. The mediator accounting module 41 is connected through the transmission channel 6 with the client block 3. The client block 3 is connected through the transmission channel 6 with the client accounting module 43. The mediator accounting module 41 is connected through the transmission channel 6 with the verifying block 5. The verifying block 5 is connected through the transmission channel 6 with the client block 3. The verifying block 5 is connected from the other side through the transmission channel 6 with the creditor's block 2. The verifying block 5 is connected from the next side through the transmission channel 6 with the provider's block 8. The mediator accounting module 41 is connected through the transmission channel 6 with the external block 7. The mediator accounting module 41 is connected through the transmission channel 6 with the provider's block 8. The provider's block 8 is connected through the transmission channel 6 with the security block 9. The security block 9 is connected from the next side with the creditor's block 2. The security block 9 is connected from the next side with the client block 3.

### Example No. 5

The connection of the internet system of verification of the identity of the client designed for providing financial loans for the market subjects pursuant to FIG. 3 that is formed by the client's block 3 i.e. the computer terminal of the customer interested in financial loan. The client's block 3 is electronically interconnected through the transmission channel 6 with the provider's block 1 that is the registration-controlling port through which the customer gets the blank form of the contract with the business conditions. The client block 3 is interconnected with the verifying block 5 that verifies the client's identity on the contract blank form on the basis of the submitted data by the concerned client. The verifying block 5 is electronically interconnected through the transmission channel 6 with the provider block 1 that receives the confirmation of the client's identity. The provider's block 1 is interconnected through the transmission channel 6 with the client's block 3 through which the client gets the identification PIN code. The client's block 3 is electronically connected through the transmission channel 6 with the provider's block 1 by the medium of which the customer concludes a contract on provision of financial loan from the provider's own resources namely with giving the identification PIN code and by filling out the prescribed blank of the contract. The provider's block 1 is connected through the transmission channel 6 from the other side with the provider's accounting module 41 of the bank block 4, which is the provider's account. The bank block 4 that is the computer terminal of the bank is made up of mutually interconnected provider's accounting module 41 and the client's accounting module 43. The client's accounting module 43 is interconnected through the transmission channel 6 with the client's block 3. The provider's accounting block 41 is interconnected through the transmission channel 6 with the provider's block 1.

### Example No. 6

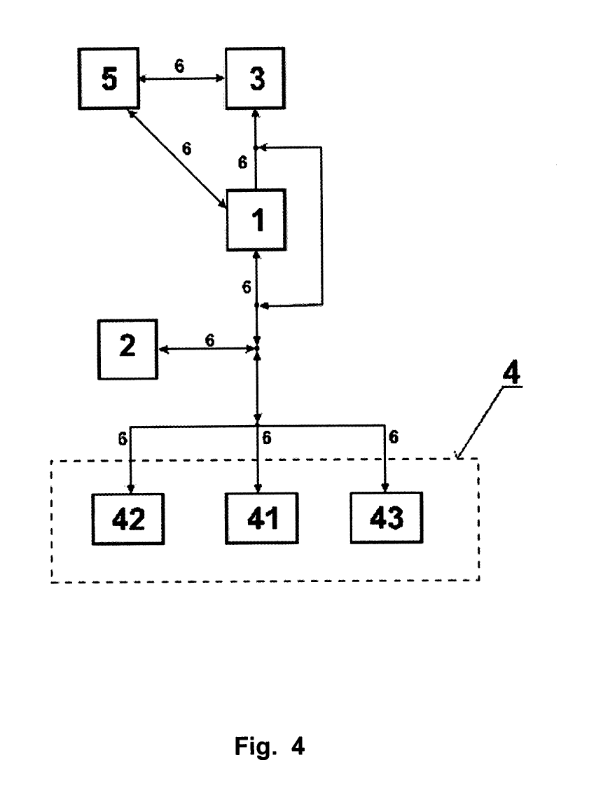

The integration of the internet system of verification of the client's identity designed for providing loans for the market subjects pursuant to FIG. 4 is formed by the client's block 3 which is the computer terminal of the customer interested in financial loan. The client's block 3 is electronically interconnected through the transmission channel 6 with the provider's block 1 that is the registration-controlling port through which the customer gets the form of the contract with the business conditions. The client's block 3 is interconnected with the verifying block 5 that verifies the client's identity on the contract blank form on the basis of the submitted data by the concerned client. The verifying block 5 is electronically interconnected through the transmission channel 6 with the provider block 1 that receives the confirmation of the client's identity. The provider's block 1 is interconnected through the transmission channel 6 with the client's block 3 through which the client gets the identification PIN code. The client's block 3 is electronically connected through the transmission channel 6 with the provider's block 1 by the medium of which the customer concludes a contract on provision of financial loan. It runs by means of giving the identification PIN code and by filling out the prescribed blank of the contract. The provider's block 1 is connected through the transmission channel 6 with the creditor's block 2 i.e. the computer terminal of provider of the financial loan. The creditor block 2 is interconnected through the transmission channel 6 with the provider's block 1. The provider's block 1 from the next side is interconnected through the transmission channel 6 with the provider's accounting block 41 of the bank block 4, which is the computer terminal of the bank. The bank block 4 is created from mutually interconnected provider's accounting module 41 and creditor's accounting module 42 and client's accounting module 43. The client's accounting module 43 is interconnected through the transmission channel 6 with the client's block 3. The creditor's accounting module 42 is interconnected through the transmission channel 6 with creditor's block 2. The provider's accounting block 41 is interconnected through the transmission channel 6 with the provider's block 1. The provider's accounting block 41 is interconnected through the transmission channel 6 with the creditor's block 2.

### Industrial Applicability

The connection in accordance with the technical solution is applicable in the money-market field, especially for the purpose of better accessibility of loans for purchasing goods and providing services both for natural and legal entities and for better appreciation of free means for natural and legal entities. Finally this will bring benefits to both of the parties, as the result will be the lower value of money for the client and higher evaluation of the free financial means for the creditor.

What is claimed is:

1. The integration of the internet system of mediation of financial loans designed for financial mediation for the market subjects is characterized by the fact that it is made up of at least one mediator block (1) connected through the transmission channel (6) with at least one creditor's block (2) and/or at least one client's block (3) and/or at least one bank block (4) which is from one side interconnected through the transmission channel (6) with at least one creditor block (2) and/or at least one client block (3) that is connected through the transmission channel (6) with at least one creditor block (2).

2. The connection according to the requirement 1 is distinguished by the fact that at least one client's block (3) that is connected through the transmission channel (6) with at least one verifying block (5) that is connected through the transmission channel (6) with at least one creditor's block (2) and/or at least one bank block (4) and/or at least one mediator block (1).

3. The connection of internet system for mediation of financial loans, purchasing goods and providing services designed for market subjects characterized by the fact that it is made up of at least one mediator's block (1) that is connected through the transmission channel (6) with at least one creditor's block (2) and/or at least one bank block (4) and/or at least one provider's block (8) a and/or at least one security block (9) and/or at least one external block (7) and/or at least one clients block (3) which is connected through the transmission channel (6) with at least one verifying block (5) which is connected through the transmission channel (6) with at least one creditor's block (2) and/or at least one provider's block (8) and/or at least one mediator's block (1).

4. Connection according to the requirement 3 is distinguished by the fact that at least one client block (3) is connected through the transmission channel (6) with at least one creditor's block (2) and/or at least one provider's block (8) and/or at least one security block (9) which is connected through the transmission channel (6) with at least one creditor's block (2) and/or at least one provider's block (8).

5. The integration of the internet system of verification of the client's identity designed for providing loans for the market subjects characterized by the fact that it is made up of at least one client's block (3) that is connected through the transmission channel (6) with at least one provider's block (1) and connected through the transmission channel (6) with at least one verifying block (5) which is connected through the transmission channel (6) with at least one provider's block (1) that is connected through the transmission channel (6) with at least one bank block (1) that is connected through the transmission channel (6) with at least one client's block (3).

6. Connection according to the requirement 5 is distinguished by the fact that at least one provider's block (1) and/or at least one client's block (3) is connected through the transmission channel (6) with at least one creditor's block (2) that is connected through the transmission channel (6) with at least bank block (1) that is connected through the transmission channel (6) with at least one client's block (3).
